(19) United States
(12) Patent Application Publication
(10) Pub. No.: US 2007/0253233 A1
(43) Pub. Date: Nov. 1, 2007

(54) Semiconductor memory device and method of production

(76) Inventors: Torsten Mueller, Dresden (DE); Peter Baars, Dresden (DE); Klaus Muemmler, Dresden (DE); Joern Regul, Dresden (DE); Christian Kapteyn, Dresden (DE)

Correspondence Address: SLATER & MATSIL LLP, 17950 PRESTON ROAD, SUITE 1000, DALLAS, TX, 75252, US

(21) Appl. No.: 11/393,363

(22) Filed: Mar. 30, 2006

(51) Int. Cl. G11C 5/02

(52) U.S. Cl. 365/51

(57) ABSTRACT

A device includes an array of memory cells, which are arranged vertically to a main substrate surface. The array is provided with lower bitlines, wordlines and upper bitlines. The lower and upper bitlines are contact-connected to lower source/drain regions and corresponding upper source/drain regions, respectively, in such a manner that a unique addressing of individual memory cells is possible.

### TECHNICAL FIELD

This invention concerns semiconductor memory devices with vertically arranged memory cells, especially charge-trapping memory cells, and a method of production.

### BACKGROUND

Semiconductor memory devices comprise arrays of memory cells, which usually have a planar transistor structure and a storage means. The memory cells are usually arranged in an array at a main surface of a semiconductor substrate. The feasible storage density is limited by the minimal area that is occupied by the transistor structures. Therefore, concepts have been developed to reduce the area that is required by the memory cell array. The substrate surface can be increased if trenches are etched in the surface and the channel and gate electrode of the transistor structure are arranged along the walls of the trenches. Another possibility is the application of semiconductor fins, strip-like structures or ridges of semiconductor material, which also aim at an enlargement of the total surface area.

### SUMMARY OF THE INVENTION

The semiconductor memory device comprises a substrate having a main surface, memory cells being arranged at the main surface, the memory cells comprising memory cell units, and each memory cell unit providing separate storage sites. The storage sites are preferably arranged at positions that correspond to corners of a cube or cuboid.

In a method for production of semiconductor memory devices, a semiconductor substrate having a main surface is provided. First trenches are etched in the surface. Lower bitlines are formed at the bottom of the trenches and covered with a trench filling. Second trenches are etched transversely to the first trenches without intersecting the lower bitlines. A gate dielectric is formed on the sidewalls of the second trenches. An electrically conductive material is applied into the second trenches to form wordlines, which are covered with a dielectric material. The trench filling is removed. Lower source/drain regions are formed by introducing doping atoms adjacent to the lower bitlines in regions between the wordlines. The first trenches are filled with a dielectric material. Upper source/drain regions are formed by introducing doping atoms. Upper bitlines are formed of electrically conductive material.

These and other features of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a schematic representation of the arrangement of wordlines, lower bitlines and upper bitlines;

FIG. 2 shows a schematic representation of an alternative arrangement of the upper bitlines;

FIG. 3 shows a schematic representation according to FIG. 2 for an alternative embodiment;

FIG. 4 shows a schematic representation according to FIG. 1 for an alternative embodiment;

FIG. 5 shows a schematic representation according to FIG. 4 for still a further embodiment;

FIG. 6 shows a plan view on the arrangement of buried bitlines and wordlines;

FIG. 7 shows a cross section of a first intermediate product of a production method;

FIG. 8 shows another cross section of the intermediate product according to FIG. 7;

FIG. 9 shows a cross section according to FIG. 7 after the formation of lower bitlines;

FIG. 10 shows a cross section according to FIG. 9 after the application of a trench filling;

FIG. 11 shows a cross section perpendicular to the cross section of FIG. 10;

FIG. 12 shows a cross section according to FIG. 11 after the deposition of wordline material;

FIG. 13 shows a cross section according to FIG. 12 after the application of upper wordline insulations;

FIG. 14 shows a cross section parallel to the cross section of FIG. 10 after the formation of the wordlines;

FIG. 15 shows a cross section according to FIG. 10 for an implantation step to form lower source/drain regions;

FIG. 16 shows a cross section according to FIG. 15 after the formation of upper source/drain regions;

FIG. 17 shows a cross section according to FIG. 16 after the formation of contact plugs and the application of a first metal level;

FIG. 18 shows an enlarged view of a cross section according to FIG. 17 after the formation of lower and upper bitlines; and

FIG. 19 shows a cross section perpendicular to the cross section of FIG. 18 through the wordlines.

### DETAILED DESCRIPTION OF ILLUSTRATIVE EMBODIMENTS

A preferred embodiment of the semiconductor memory device comprises a substrate having a main surface, bitlines formed at the main surface, the bitlines running parallel at a distance from one another, wordlines formed at the main surface, the wordlines running parallel at a distance from one another and transversely to the bitlines, memory cell units arranged at the main surface, each occupying an area of the main surface that is limited by contours of two neighboring ones of the bitlines and contours of two neighboring ones of the wordlines, and every memory cell unit providing eight separate storage sites. The storage sites are preferably arranged at positions that correspond to corners of a cube or cuboid.

In a further aspect, the semiconductor memory device comprises a substrate having a main surface, lower bitlines formed in the substrate at the main surface, the lower bitlines running parallel at a distance from one another, parallel wordlines at a distance from one another above the lower bitlines and transverse to the lower bitlines, memory cell bodies of semiconductor material located between the wordlines and comprising lower and upper portions, a gate dielectric between the wordlines and the memory cell bodies, the gate dielectric comprising a memory layer as a storage means, upper bitlines arranged above the wordlines and running parallel at a distance from one another transversely to the wordlines, lower source/drain regions formed at the lower portions of the memory cell bodies adjacent to the lower bitlines, upper source/drain regions formed in the upper portions of the memory cell bodies, the lower bitlines electrically connecting a plurality of the lower source/drain regions, and the upper bitlines electrically connecting a plurality of the upper source/drain regions.

In a preferred embodiment, every lower bitline electrically connects a corresponding plurality of lower source/drain regions that comprise at least one lower source/drain region in every area between two neighboring wordlines, and every upper bitline electrically connects a corresponding plurality of upper source/drain regions that comprise upper source/drain regions that are located above corresponding lower source/drain regions in such a manner that in each case two lower source/drain regions that correspond to two upper source/drain regions succeeding one another along the corresponding upper bitline are connected to different lower bitlines.

Every lower bitline can electrically connect a corresponding plurality of lower source/drain regions that comprise two lower source/drain regions in every area between two neighboring wordlines.

The upper source/drain regions can each be located above two corresponding lower source/drain regions, one of which is connected to a corresponding first lower bitline and the other one is connected to a corresponding second lower bitline, the corresponding first and second lower bitlines being located neighboring to one another. Additionally, every upper bitline can electrically connect a corresponding plurality of upper source/drain regions that comprise upper source/drain regions that are located above lower source/drain regions that are, in their succession along the corresponding upper bitline, alternatingly connected to one of two neighboring lower bitlines.

An especially preferred embodiment comprises separate upper source/drain regions that are each located above one corresponding lower source/drain region.

Every upper bitline can electrically connect a corresponding plurality of upper source/drain regions in such a fashion that the corresponding lower source/drain regions are, in their succession along the corresponding upper bitline, located on different sides of a lower bitline. Every upper bitline can electrically connect a corresponding plurality of upper source/drain regions in such a fashion that the corresponding lower source/drain regions are, in their succession along the corresponding upper bitline, alternatingly connected to one of two neighboring lower bitlines and are alternatingly located on different sides of a lower bitline. Instead, every upper bitline can electrically connect a corresponding plurality of upper source/drain regions in such a fashion that the corresponding lower source/drain regions are, in their succession along the corresponding upper bitline, connected sequentially to lower bitlines that follow one another in a direction of the wordlines.

The lower bitlines can be rectilinear or wriggled in zigzag fashion, and the upper bitlines can be rectilinear or wriggled in zigzag fashion. The upper bitlines can especially be wriggled in a sense that is opposite to the lower bitlines.

In a further aspect, the semiconductor memory device comprises a semiconductor substrate having a main surface, lower bitlines formed in the substrate at the main surface, lower source/drain regions adjacent to the lower bitlines, trenches in the semiconductor substrate above the lower bitlines and running parallel at a distance from one another transversely to the lower bitlines, wordlines being arranged in the trenches and being separated by a gate dielectric from the semiconductor substrate, the gate dielectric comprising a memory layer, upper source/drain regions in the vicinity of the wordlines, upper bitlines contact-connected to a plurality of upper source/drain regions, and memory cells, which are each addressed by one wordline and comprise a lower source/drain region and an upper source/drain region, the lower bitlines and the upper bitlines being connected to pluralities of lower source/drain regions and upper source/drain regions, respectively, in such a manner that every two memory cells that are addressed by the same wordline comprise connections of their lower source/drain regions to different lower bitlines and/or connections of their upper source/drain regions to different upper bitlines.

The lower bitlines can be formed as doped regions in the semiconductor substrate or with electrically conductive material like metal, especially tungsten, electrically conductively doped polysilicon, electrically conductively doped SiGe or electrically conductive carbon. The wordlines can comprise, for example, a metal, especially TiN, electrically conductively doped polysilicon, electrically conductively doped SiGe or electrically conductive carbon. In a further preferred embodiment having charge-trapping memory cells, the gate dielectric can comprise at least one dielectric material that is suitable for charge-trapping.

A method for production comprises the steps of providing a semiconductor substrate having a main surface, etching first trenches running parallel at a distance from one another into the main surface, forming lower bitlines at the bottom of the first trenches, covering the lower bitlines with a trench filling, etching second trenches running parallel at a distance from one another transversely to the first trenches without intersecting the lower bitlines, arranging a dielectric material in the bottoms of the second trenches, forming a gate dielectric on sidewalls of the second trenches, depositing an electrically conductive material into the second trenches above the dielectric material to form wordlines, covering the wordlines with a dielectric material, removing the trench filling, forming lower source/drain regions by an introduction of doping atoms adjacent to the lower bitlines in regions between the wordlines, filling the first trenches with a dielectric material, forming upper source/drain regions by introducing doping atoms, and forming upper bitlines of electrically conductive material, each of them contact-connecting pluralities of upper source/drain regions.

The method can further comprise the step of forming the lower bitlines by a deposition of an electrically conductive material into the first trenches. The lower bitlines can also be produced by an introduction of doping atoms into the bottoms of the first trenches.

The lower source/drain regions can be produced by an application of a doped semiconductor material to sidewalls of the first trenches and a subsequent outdiffusion of doping atoms into the adjacent semiconductor material of the substrate. In order to obtain doped regions with very small dimensions, the doped semiconductor material is applied to fill a small opening. Subsequently, a surplus of the doped semiconductor material is removed to leave a small amount just filling the opening. This method is known per se by the name of divot fill. The outdiffusion of the doping atoms can thereby be restricted to a very small region. Instead or additionally, the lower source/drain regions can be produced by a tilted implantation of doping atoms into sidewalls of the first trenches.

It is not necessary to arrange the upper bitlines in only one metallization level; instead, they can be arranged in at least two metallization levels. In principle, embodiments of this invention enable reduction of the device area that is occupied by every unit cell down to 6F²; but then it may not be possible to arrange the bitline contacts on the same level, and an arrangement of the upper bitlines in several metallization levels will be necessary.

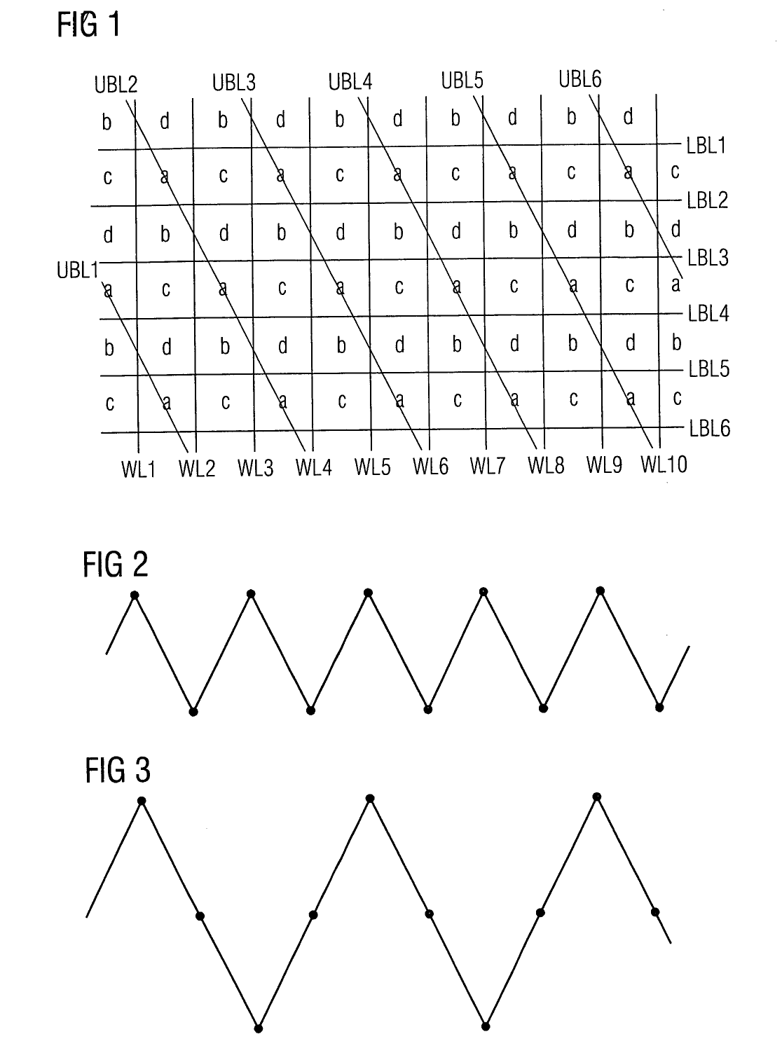

FIG. 1 shows a schematic representation of the arrangement of wordlines WL, lower bitlines LBL, and upper bitlines UBL. The lower bitlines connect rows of lower source/drain regions, and the upper bitlines connect pluralities of upper source/drain regions in such a manner that each memory cell can be addressed by the selection of one lower bitline, one upper bitline and one wordline. The individual memory cells are arranged vertically so that the channel extends between a lower source/drain region and an upper source/drain region. The embodiment of FIG. 1 comprises upper source/drain regions, which are designated in each case by a small letter, in the area that is limited in the plan view by the vertical projection of pairs of lower bitlines and pairs of wordlines. There are separate lower source/drain regions on both sides of each lower bitline. Every upper source/drain region belongs to memory cells that are addressed by neighboring wordlines and neighboring lower bitlines. Thus, the quadruples of upper source/drain regions that are arranged in a rectangle and designated with letters a, b, c, and d are simultaneously addressed by a selected wordline and a selected lower bitline.

The upper bitlines are arranged in such a manner that the four upper source/drain regions of each quadruple are contacted by four different upper bitlines. This can be effected, for instance, by the structure shown in FIG. 1, where only upper bitlines connecting source/drain regions that are designated “a” are drawn. The other upper bitlines are left out in the drawing in order not to obfuscate it with a thick pattern of lines. The upper bitlines connecting the source/drain regions that are designated with b, c, and d, respectively, are arranged parallel to the upper bitlines shown in FIG. 1. Any quadruple of four adjacent upper source/drain regions designated with a, b, c, and d, which are simultaneously addressed by the same wordline and the same lower bitline is contacted by four different upper bitlines in this way.

FIG. 2 shows another shape of the upper bitlines, which also renders a unique addressing scheme of the memory cells. A conductor track like that represented in FIG. 2 fits to connect upper source/drain regions in a plurality of locations designated with the same small letter, and can be arranged parallel to further conductor tracks of the same shape to provide a complete wiring of the memory cells. The locations of the contacts are marked with fat dots on the line that represents the conductor track.

FIG. 3 shows an alternative to the conductor track of FIG. 2, which comprises longer straight sections, which each connect three of the upper source/drain regions. The locations of the contacts are again indicated with fat dots on the line that represents the conductor track. The straight sections may be even longer and may in principle comprise any number of contacts.

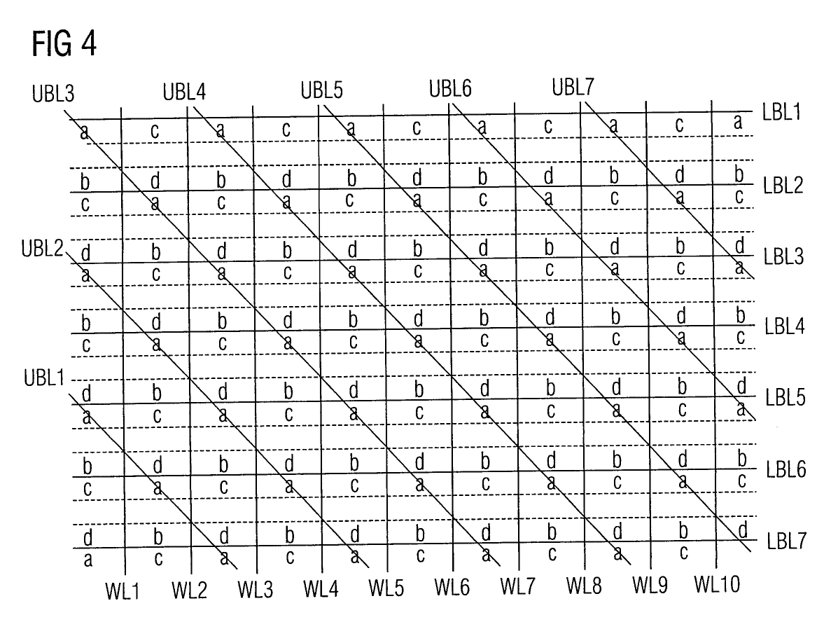

FIG. 4 shows a schematic representation of the arrangement of wordlines, lower bitlines and upper bitlines according to FIG. 1 for another embodiment, which comprises two separate upper source/drain regions in each area between the vertical projections of the lower bitlines into the plane of the main surface. Every lower source/drain region that is located adjacent to a lower bitline is provided with a corresponding upper source/drain region. In FIG. 4, the upper bitlines that have been drawn connect the source/drain regions designated “a.” The other upper bitlines run parallel to these upper bitlines and connect upper source/drain regions that are designated with the same letter b, c, and d, respectively. In this embodiment as well, it is possible to have a wriggled shape of the upper bitlines in the zigzag fashion shown in FIG. 2 or FIG. 3.

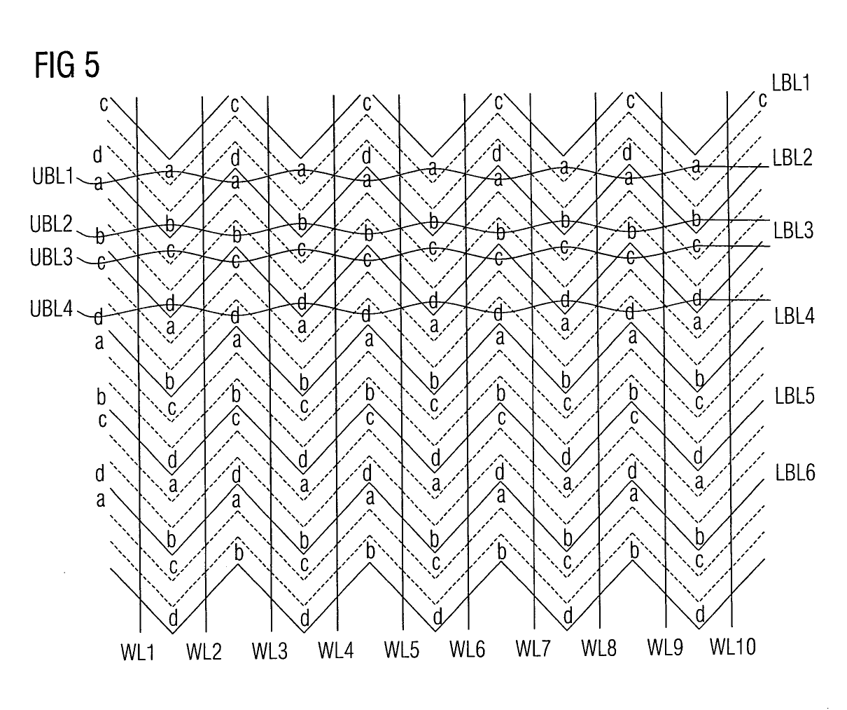

Another embodiment is shown in FIG. 5 in a schematic representation according to FIG. 4. In this embodiment there are separate upper source/drain regions corresponding to separate lower source/drain regions as in the embodiment according to FIG. 4. But the lower bitlines are wriggled in zigzag fashion so that it is possible to connect pluralities of upper source/drain regions that are designated with the same small letter by rectilinear upper bitlines or at least by upper bitlines that are less curved than the lower bitlines. In this example according to FIG. 5, four neighboring upper bitlines are drawn, which connect upper source/drain regions designated with a, b, c, and d, respectively, in a direction perpendicular to the wordlines. The arrangements and shapes of the upper and lower bitlines can vary as long as a unique addressing of the individual memory cells is achieved.

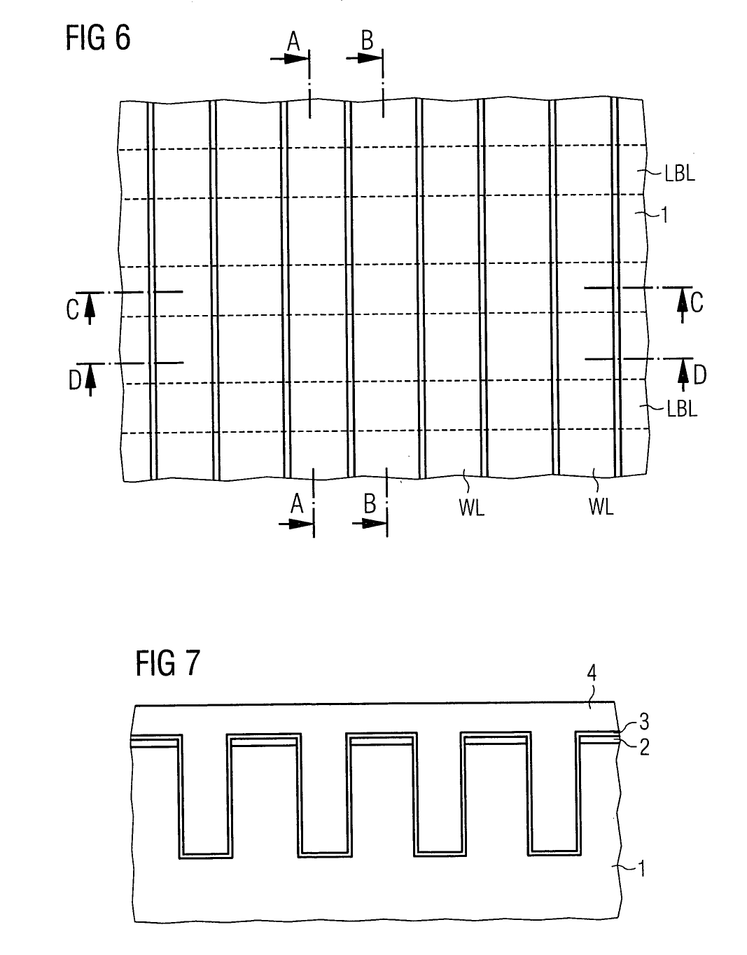

The structure of the semiconductor memory device will become apparent from the following description of a preferred embodiment in conjunction with the appended figures. FIG. 6 shows a plan view on the arrangement of wordlines and lower bitlines at a main surface of a semiconductor substrate. This embodiment comprises straight lower bitlines. The positions of cross sections A, B, C, and D are indicated for further reference.

FIG. 7 shows a cross section of a first intermediate product of a preferred method of production. A main surface of a substrate 1 of semiconductor material is provided with a pad nitride 2. Parallel trenches are etched into the main surface. Preferably, at least one liner 3 is deposited, which may be oxide. A further liner can be provided to prevent a silicidation of an electrically conductive material 4, which is then filled into the trenches. If the electrically conductive material 4 is tungsten, for example, a further liner preferably comprises Ti or/and TiN. The electrically conductive material 4 is provided for the lower bitlines and can be a metal. It can also be electrically conductively doped polysilicon, electrically conductively doped SiGe or electrically conductive carbon, which can be applied by pyrolytic deposition. Alternatively to the deposition of an electrically conductive material as described here in conjunction with a preferred embodiment, the lower bitlines can also be doped regions in the semiconductor material, formed by an implantation or diffusion of doping atoms, for example. The position of the cross section of FIG. 7 corresponds to the cross sections A and B in FIG. 6.

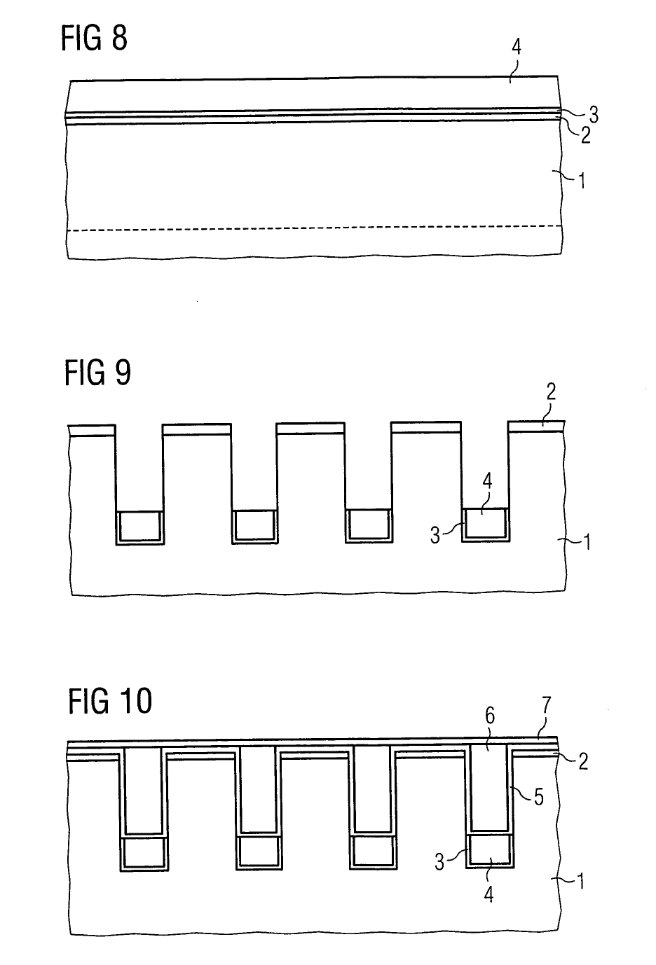

FIG. 8 shows a cross section of the intermediate product according to FIG. 7 in a perpendicular cross section along line D in FIG. 6. The broken horizontal line in FIG. 8 indicates the concealed contour of the bottom of a trench. It would be a lower boundary line of the trench in a cross section at position C in FIG. 6, across the region that is provided for the lower bitlines.

FIG. 9 shows the cross section according to FIG. 7 after recessing the electrically conductive material 4 and the liner. The residual portions of the electrically conductive material 4 form conductor tracks that are provided for the lower bitlines. Any oxide is removed from the sidewalls of the trenches above the electrically conductive material 4.

FIG. 10 shows the cross section according to FIG. 9 after the application of a further liner 5, preferably of nitride, to the sidewalls of the trenches. Nitride may also be deposited on top of the pad nitride 2. The trenches are then filled with an auxiliary filling 6, which may be polysilicon. The filling is planarized, which may be effected by chemical mechanical polishing. A further liner 7 is preferably deposited, which can also be nitride. The wordlines are arranged across the lower bitlines in trenches that are etched transversely to the trenches of the lower bitlines.

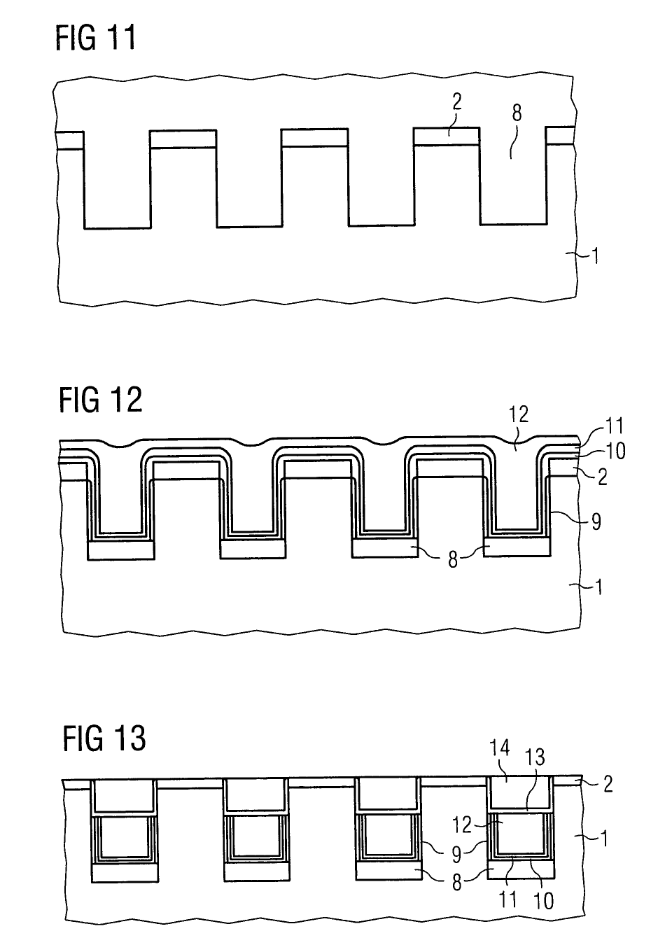

FIG. 11 shows a cross section at location D in FIG. 6, between neighboring lower bitlines. Further trenches are etched into the substrate 1, which are provided for the wordlines and are arranged parallel to one another at a distance from one another. The further trenches can be etched down to the upper surfaces of the electrically conductive material 4 that is provided for the lower bitlines. Since the bitlines are not to be etched, the etching process preferably stops on the further liner 5. The further trenches define active areas between the intended wordlines. The active areas are periodically interrupted by the auxiliary filling 6 that has been applied above the lower bitlines. This is not shown in FIG. 11, since FIG. 11 shows the cross section between the lower bitlines. In order to provide an electric insulation between the lower bitlines and the wordlines, a dielectric material 8 is filled into the further trenches. The dielectric material 8 can be oxide, for example, which can be deposited from a high-density plasma. After a planarization of the dielectric material 8, it is etched back to form shallow residual portions at the bottoms of the further trenches. Thus electrical insulations are formed on the lower bitlines.

FIG. 12 shows the cross section according to FIG. 11 after the partial removal of the dielectric material 8 to form the electrically insulating regions at the bottom of the further trenches. A first gate dielectric 9 is formed on the sidewalls of the further trenches, preferably by an oxidation of the semiconductor material. In this embodiment, a second gate dielectric 10 is applied, preferably by a deposition of nitride, and a third gate dielectric 11, which is preferably oxide, which can be deposited or formed by a re-oxidation of the nitride layer of the second gate dielectric 10. Such a layer sequence of dielectric materials forming the complete gate dielectric is optional but is especially preferred if the memory cells are to be realized as charge-trapping memories comprising charge-trapping layer sequences. The second gate dielectric 10 then forms the memory layer for charge trapping, while the first gate dielectric 9 and the third gate dielectric 11 form the boundary layers. The oxide-nitride-oxide layer sequence thus forms the storage means of the memory cells.

If the memory cells are charge-trapping memory cells, the memory layer sequence between the wordlines and the channel regions at the sidewalls between upper and lower source/drain regions can be oxide-nitride-oxide layer sequences or other layer sequences comprising at least one dielectric material that is suitable for charge-trapping. The memory layer can especially be a dielectric material that comprises silicon nanocrystals. These materials are known per se from other charge-trapping memory devices.

A further electrically conductive material 12, which can be the same material as the electrically conductive material 4 provided for the lower bitlines, is applied into the further trenches and is provided for the wordlines. The wordlines can be a metal, including TiN, for instance, electrically conductive polysilicon, SiGe or carbon. The electrically conductive material 12 is etched back so that recesses above the residual portions are formed in every further trench. The remaining layers of the electrically conductive material 12 form the conductor tracks of the wordlines.

FIG. 13 shows the cross section according to FIG. 12 after the shaping of the electrically conductive material 12 into the conductor tracks of the wordlines, the application of an optional further liner 13, which can be nitride, and a filling of a dielectric material 14. The dielectric material 14 can be oxide. In the preferred embodiment according to FIG. 13, the materials of the gate dielectric have been removed before the application of the further liner 13. The dielectric material 14 forms upper electric insulations of the wordlines 12.

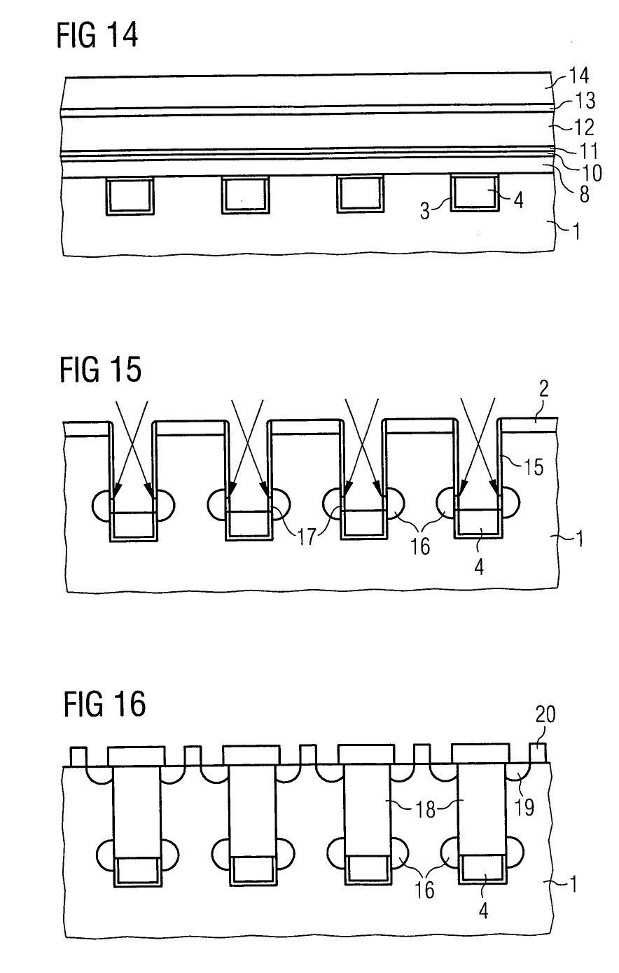

FIG. 14 shows a cross section of the intermediate product according to FIG. 13 at position A in FIG. 6, intersecting one of the wordlines along its longitudinal extension. The reference numerals are the same as in FIGS. 10 and 13; they need not be described again.

The residual auxiliary filling 6 is selectively removed to form openings above the lower bitlines in the areas between the wordlines. The upper surfaces of the electrically conductive material 4 provided for the lower bitlines are laid bare in these openings. Preferably, a further liner 15 is applied to the sidewalls formed by the openings to protect the gate dielectric in the corners of the openings. The further liner 15 can be nitride. The material of the further liner 15 is removed in shallow areas immediately above the electrically conductive material 4. Thereby the electrically conductive material 4 can slightly be recessed. A tilted implant of doping atoms approximately in the directions indicated by the arrows in FIG. 15 is performed to form lower source/drain regions 16 in the vicinity of the upper edges of the electrically conductive material 4. Instead of a tilted implantation, small pads of doped semiconductor material 17, preferably doped polysilicon, can be deposited in the manner known per se as divot fill. The doping atoms are diffused from the doped semiconductor material 17 in a subsequent thermal diffusion step. The diffusion of the doping atoms forms the lower source/drain regions 16. If it is favorable, both the tilted implantation and the diffusion out of a divot fill can be combined to form the lower source/drain regions 16 as doped regions. Then the further liner 15 is stripped, and the openings are filled with dielectric material.

FIG. 16 shows the cross section according to FIG. 15, after the dielectric material 18, which can be oxide, has been filled into the openings and provided with planarized upper surfaces. This is preferably effected by chemical mechanical polishing. The pad nitride is removed; and a dielectric layer 20 is applied to the main surface and provided with openings in the areas in which contact plugs are to be arranged. The dielectric layer 20 also serves as a mask in a subsequent implantation step, by which a dopant is introduced to form the upper source/drain regions 19. In the embodiment shown in FIG. 16, separate upper source/drain regions 19 are formed corresponding to the separate lower source/drain regions 16. Thus there are pairs of upper and lower source/drain regions that correspond to each other and form the source/drain regions of the individual memory cells, which are arranged in the direction that is vertical to the main surface of the substrate. Instead, a continuous upper source/drain region can be implanted in the area between the vertical projections of two neighboring lower bitlines and two neighboring wordlines.

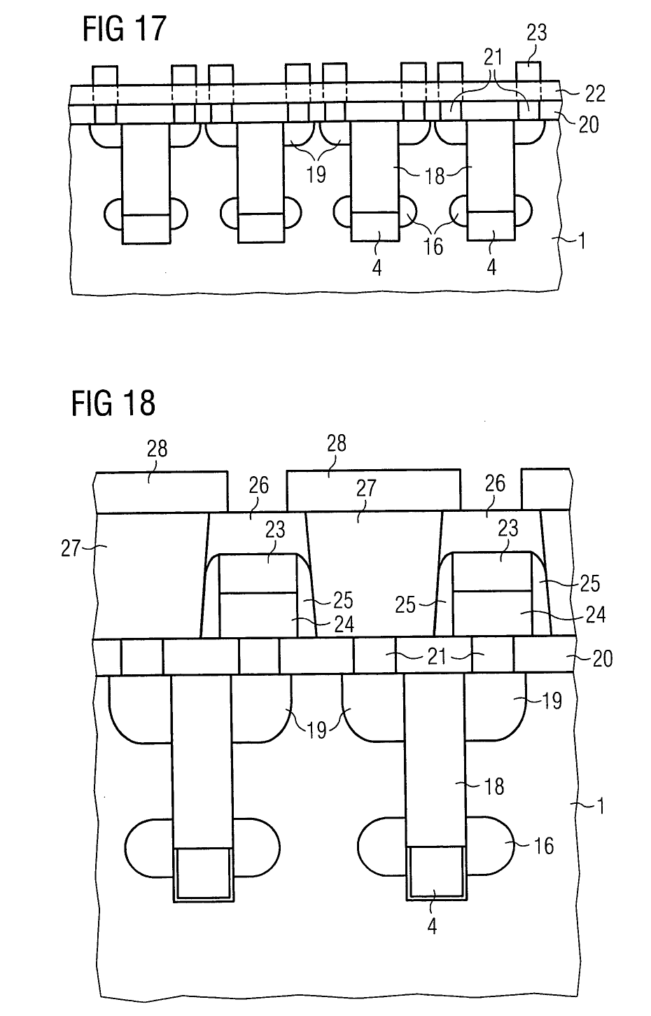

FIG. 17 shows the cross section according to FIG. 16 after the formation of contact plugs 21 in the openings of the dielectric layer 20 above the upper source/drain regions 19. Then the first metal layer, in this example the M0 metal level, is applied. A mask 23, preferably a hardmask formed of nitride, serves to etch the M0 metal level 22 into conductor tracks forming first upper bitlines, which contact the electric connections to the upper source/drain regions 19.

FIG. 18 shows the cross section of FIG. 17 after the formation of the first upper bitlines 24, which, in this example, individually connect every second contact plug 21 in a row along the wordlines, the application of sidewall spacers 25 to the stacks that are formed of the mask 23 and the first upper bitlines 24, and the application of an intermetal dielectric 26. The sidewall spacers 25 can be of the same material as the material of the mask 23, preferably nitride. The intermetal dielectric 26 can be any dielectric that is commonly used as an insulation between the metal levels of the wiring metallizations. It can especially be boron phosphorus silicate glass.

Vias 27, filled with electrically conductive material, are provided in the intermetal dielectric 26 as electric connections to the other contact plugs 21 that are not connected with the first upper bitlines 24. The vias 27 are contacted above by second upper bitlines 28. The upper bitlines can thus be arranged in at least two different metal levels. This is especially advantageous if the lateral dimensions of the upper bitlines and the interspaces between the upper bitlines would have to be too small to be arranged in the same metal level, as in the cross section of FIG. 17. In this case, the vias 27 are produced self-aligned to the stacks of the first upper bitlines.

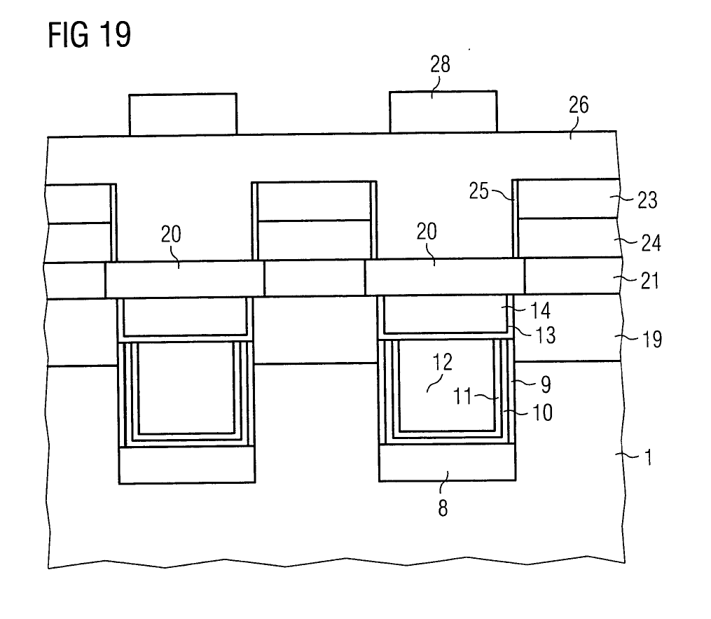

FIG. 19 shows the cross section of the embodiment according to FIG. 18 at position D in FIG. 6, transversely to the wordlines and between the lower bitlines. The reference numerals are the same as in the preceding figures and designate the same elements. FIG. 19 shows that the second upper bitlines 28 run across the wordlines without contacting them. The second upper bitlines 28 contact upper source/drain regions 19 before and behind the drawing plane in the areas between two neighboring wordlines. Possible relative arrangements of the contacts and electrical connections between the upper source/drain regions 19 and the upper bitlines 24, 28 can easily be inferred from a comparison between FIGS. 18, 19 and FIGS. 1 to 5. The second upper bitlines 28 are preferably formed in the M1 metal level.

The described production method can be used in a similar way to produce semiconductor devices with wriggled lower bitlines and wriggled or rectilinear upper bitlines. In general, every layout of lower bitlines, wordlines and upper bitlines is feasible that allows to address a certain memory cell by a selection of one lower bitline, one wordline and one upper bitline. Especially the arrangement of the upper bitlines is appropriately designed to enable a unique addressing of the memory cells, as has already been described in conjunction with FIGS. 1 to 5.

It is especially favorable to have a charge-trapping memory layer sequence as gate dielectric, because this enables an effective and reliable storage of bits of information at both channel ends. If there is only one continuous upper source/drain region in each area between the vertical projections of two lower bitlines and two neighboring wordlines into the plane of the main surface, a respective upper source/drain region belongs to two adjacent memory cells that are addressed by the same wordline and the same upper bitline. In this case, the number of storable bits is six per upper source/drain region, because the upper source/drain region is located at a channel end that is common to two memory cells, while the corresponding two separate lower source/drain regions are located at separate opposite channel ends of the relevant memory cells. The embodiment with separate upper source/drain regions as described in conjunction with the production method allows the storage of a total of eight bits in the same area.

Although the present invention and its advantages have been described in detail, it should be understood that various changes, substitutions and alterations can be made herein without departing from the spirit and scope of the invention as defined by the appended claims.

What is claimed is:

1. A semiconductor memory device, comprising:
a substrate having a main surface; and
memory cells being arranged at the main surface, the memory cells comprising memory cell units, each memory cell unit providing eight separate storage sites.

2. The semiconductor memory device according to claim 1, wherein the storage sites are arranged at positions that correspond to corners of a cube or cuboid.

3. A semiconductor memory device, comprising:
a substrate comprising a main surface;
bitlines formed at the main surface, the bitlines running parallel at a distance from one another;
wordlines formed at the main surface, the wordlines running parallel at a distance from one another and transversely to the bitlines;
memory cell units arranged at the main surface, each memory cell unit occupying an area of the main surface that is limited by contours of two neighboring bitlines and contours of two neighboring wordlines, wherein each memory cell unit provides eight separate storage sites.

4. The semiconductor memory device according to claim 3, wherein the storage sites are arranged at positions that correspond to corners of a cube or cuboid.

5. A semiconductor memory device, comprising:
a substrate comprising a main surface;
lower bitlines formed in the substrate at the main surface, the lower bitlines running parallel at a distance from one another;
wordlines arranged above the lower bitlines, the wordlines running parallel at a distance from one another and transversely to the lower bitlines;
memory cell bodies of semiconductor material located between the wordlines and comprising lower and upper portions;
a gate dielectric, wherein the wordlines are separated from the memory cell bodies by the gate dielectric, the gate dielectric comprising a memory storage layer;
upper bitlines arranged above the wordlines, the upper bitlines running parallel at a distance from one another and transversely to the wordlines;
lower source/drain regions formed at the lower portions of the memory cell bodies adjacent to the lower bitlines, the lower bitlines electrically connecting a plurality of the lower source/drain regions; and
upper source/drain regions formed in the upper portions of the memory cell bodies, the upper bitlines electrically connecting a plurality of the upper source/drain regions.

6. The semiconductor memory device according to claim 5, wherein:
every lower bitline electrically connects a corresponding plurality of the lower source/drain regions, said plurality comprising at least one lower source/drain region in every area between two neighboring wordlines; and
every upper bitline electrically connects a corresponding plurality of the upper source/drain regions, said plurality comprising upper source/drain regions that are located above corresponding lower source/drain regions in such a manner that in each case two lower source/drain regions that correspond to two upper source/drain regions succeeding one another along the corresponding upper bitline are connected to different lower bitlines.

7. The semiconductor memory device according to claim 5, wherein every lower bitline electrically connects a corresponding plurality of the lower source/drain regions, said plurality comprising two lower source/drain regions in every area between two neighboring wordlines.

8. The semiconductor memory device according to claim 7, wherein the upper source/drain regions are each located above two corresponding lower source/drain regions, one of the lower source/drain regions being connected to a corresponding first one of the lower bitlines and the other one of the lower source/drain regions being connected to a corresponding second one of the lower bitlines, the corresponding first and second ones of the lower bitlines being located neighboring to one another.

9. The semiconductor memory device according to claim 8, wherein every upper bitline electrically connects a corresponding plurality of the upper source/drain regions, said plurality comprising upper source/drain regions that are located above lower source/drain regions that are, in their succession along the corresponding upper bitline, alternatingly connected to one of two neighboring lower bitlines.

10. The semiconductor memory device according to claim 7, wherein the upper source/drain regions are each located above one corresponding lower source/drain region.

11. The semiconductor memory device according to claim 10, wherein every upper bitline electrically connects a corresponding plurality of the upper source/drain regions in such a fashion that the corresponding lower source/drain regions are, in their succession along the corresponding upper bitline, located on different sides of one of the lower bitlines.

12. The semiconductor memory device according to claim 11, wherein every upper bitline electrically connects a corresponding plurality of the upper source/drain regions in such a fashion that the corresponding lower source/drain regions are, in their succession along the corresponding upper bitline, alternatingly connected to one of two neighboring lower bitlines and are alternatingly located on different sides of one of the lower bitlines.

13. The semiconductor memory device according to claim 11, wherein every upper bitline electrically connects a corresponding plurality of the upper source/drain regions in such a fashion that the corresponding lower source/drain regions are, in their succession along the corresponding upper bitline, connected sequentially to lower bitlines that follow one another in a direction of the wordlines.

14. The semiconductor memory device according to claim 5, wherein the lower bitlines are rectilinear and the upper bitlines being wriggled in zigzag fashion.

15. The semiconductor memory device according to claim 5, wherein the lower bitlines are wriggled in zigzag fashion.

16. The semiconductor memory device according to claim 15, wherein the upper bitlines are wriggled in an opposite sense as compared to the lower bitlines.

17. A semiconductor memory device, comprising:
a semiconductor substrate comprising a main surface;
lower bitlines formed in the semiconductor substrate at the main surface;
lower source/drain regions adjacent to the lower bitlines;
trenches in the semiconductor substrate above the lower bitlines and running parallel at a distance from one another transversely to the lower bitlines;
wordlines arranged in the trenches, the wordlines separated from the semiconductor substrate by a gate dielectric, the gate dielectric comprising a memory layer;
upper source/drain regions arranged in the vicinity of the wordlines;
upper bitlines contact-connected to a plurality of the upper source/drain regions; and
memory cells, each memory cell being addressed by one of the wordlines and comprising one of the lower source/drain regions and one of the upper source/drain regions;
wherein the lower bitlines and the upper bitlines are connected to pluralities of lower source/drain regions and upper source/drain regions, respectively, in such a manner that every two memory cells that are addressed by the same wordline comprise at least one of connections of their lower source/drain regions to different lower bitlines and connections of their upper source/drain regions to different upper bitlines.

18. The semiconductor memory device according to claim 17, wherein the lower bitlines are formed by doped regions in the semiconductor substrate.

19. The semiconductor memory device according to claim 17, wherein the lower bitlines comprise tungsten.

20. The semiconductor memory device according to claim 17, wherein the lower bitlines comprise electrically conductively doped polysilicon.

21. The semiconductor memory device according to claim 17, wherein the lower bitlines comprise electrically conductively doped SiGe.

22. The semiconductor memory device according to claim 17, wherein the lower bitlines comprise electrically conductive carbon.

23. The semiconductor memory device according to claim 17, wherein the wordlines comprise TiN.

24. The semiconductor memory device according to claim 17, wherein the wordlines comprise electrically conductively doped SiGe.

25. The semiconductor memory device according to claim 17, wherein the wordlines comprise electrically conductively doped polysilicon.

26. The semiconductor memory device according to claim 17, wherein the wordlines comprise electrically conductive carbon.

27. The semiconductor memory device according to claim 17, wherein the gate dielectric comprises at least one dielectric material that is suitable for charge-trapping.

28. A method of producing a semiconductor memory device, the method comprising:
providing a semiconductor substrate having a main surface;
etching first trenches running parallel at a distance from one another in the main surface;
forming lower bitlines at a bottom of the first trenches;
covering the lower bitlines with a trench filling;
etching second trenches comprising bottoms and sidewalls and running parallel at a distance from one another and transversely to the first trenches without intersecting the lower bitlines;
arranging a dielectric material in the bottoms of the second trenches;
forming a gate dielectric on the sidewalls of the second trenches;
depositing an electrically conductive material into the second trenches above the dielectric material to form wordlines;
covering the wordlines with a dielectric material;
removing the trench filling;
forming lower source/drain regions by introducing doping atoms adjacent to the lower bitlines in regions between the wordlines;
filling the first trenches with a dielectric material;
forming upper source/drain regions by introducing doping atoms; and
forming upper bitlines of electrically conductive material, each one of the upper bitlines contact-connecting pluralities of the upper source/drain regions.

29. The method according to claim 28, wherein forming the lower bitlines comprises depositing an electrically conductive material into the first trenches.

30. The method according to claim 28, wherein forming the lower bitlines comprises introducing doping atoms into the bottoms of the first trenches.

31. The method according to claim 28, wherein forming the lower source/drain regions comprises:
applying a doped semiconductor material to sidewalls of the first trenches; and
producing an outdiffusion of doping atoms from the doped semiconductor material into adjacent semiconductor material of the semiconductor substrate.

32. The method according to claim 28, wherein forming the lower source/drain regions comprises forming the lower source/drain regions by a tilted implantation of doping atoms into sidewalls of the first trenches.

33. The method according to claim 28, wherein the upper bitlines are formed in at least two metallization levels.

34. The method according to claim 28, wherein the lower bitlines are formed in zigzag fashion.

35. The method according to claim 28, wherein the upper bitlines are formed in zigzag fashion.

36. The method according to claim 28, wherein forming the gate dielectric comprises forming at least one dielectric material that is suitable for charge-trapping.
